(19) United States
(12) Patent Application Publication
(10) Pub. No.: US 2006/0237736 A1
(43) Pub. Date: Oct. 26, 2006

(54) Light-emitting diode and method for improving emitting directivity of light-emitting chip

(75) Inventor: Tai-Cherng Yu, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/377,696

(22) Filed: Mar. 16, 2006

(30) Foreign Application Priority Data
Apr. 22, 2005 (CN) 200510034361.9

(51) Int. Cl. H01L 33/00

(52) U.S. Cl. 257/98

(57) ABSTRACT

A light-emitting diode (20) includes: a first electrode (202) with a supporting portion (201); a second electrode (203) opposite to the first electrode; a light-emitting chip (204) on the supporting portion, the light-emitting chip is electrically connected to the first electrode and the second electrode; and a cover (205) has a transparent aspheric portion (206), enclosing the light-emitting chip, the first electrode and the second electrode. The aspheric portion of the cover collimates light beams from the light-emitting chip so that emission performance of the light-emitting diode can be improved. A method for improving emitting directivity of light beams emitted from the light-emitting chip is also provided.

### TECHNICAL FIELD

The invention generally relates to light-emitting diodes, and more particularly to a light-emitting diode with improved emission performance. The invention also relates to a method for improving emitting directivity of a light-emitting chip.

### BACKGROUND

Light-emitting diodes are semiconductor devices that, due to the nature of the bonding of electron and hole that occurs in the semiconductor solid, can convert electrical energy directly into light. The type of bonding in a solid is directly related to the conductivity of the semiconductor solid. Metals, nonmetals, and semimetals have different bonding properties that lead to the differences in conductivity that can be observed between these materials. Light-emitting diodes rely on these different bonding properties to emit light.

Referring to FIG. 3, a conventional light-emitting diode 10 is shown. The light-emitting diode 10 includes a light-emitting chip 101 for emitting light, a horn-shaped reflector 102, and a body 103 having a light-emitting surface 104. However, due to the light-emitting surface 104 of the body 103 being a spherical surface, light beams emitted from the light-emitting chip 101 are dispersed after they pass through the light-emitting surface 104 of the body 103. This dispersion decreases the luminous efficiency of the light-emitting diode 10, thereby decreasing also the emission performance of the light-emitting diode 10.

What is needed, therefore, is a light-emitting diode for eliminating the aberration of the light-emitting diode and a method for improving emitting directivity of light beams emitted from a light-emitting chip.

### SUMMARY

In one preferred embodiment, a light-emitting diode includes: a first electrode having a supporting portion; a second electrode opposite to the first electrode; a light-emitting chip configured for emitting light beams therefrom; and a cover enclosing the light-emitting chip, and portions of the first and second electrodes therein. The light-emitting chip is disposed on the supporting portion, and electrically connected to the first electrode and the second electrode. The cover has a transparent aspheric portion configured for converging the light beams emitted from the light-emitting chip.

Preferably, the aspheric portion is an ellipsoidal portion, a hyperbolic portion or a parabolic portion.

The light-emitting diode of the described embodiment has the following advantage. The aspheric portion can eliminate an aberration of the light-emitting diode as well as collimate light beams from the light-emitting chip so that the emission performance of light-emitting diode is improved over that of a light-emitting diode with a spherical surface.

In another preferred embodiment, A method for improving emitting directivity of light beams emitted from a light-emitting chip is provided. The method includes the steps in no particular of: providing a cover having a transparent aspheric portion; providing a reflection mirror having a curved reflection surface; providing a light-emitting chip for emitting first light beams emitted toward the transparent aspheric portion, and second light beams emitted toward the curved reflection surface; arranging the reflection mirror to surround the light-emitting chip so as to reflect the second light beams toward the transparent aspheric portion; disposing the light-emitting chip in the cover in a manner such that the first and second light beams exiting from the cover are directed to emit toward a substantially common direction.

### BRIEF DESCRIPTION OF THE DRAWINGS

Many aspects of the light-emitting diode can be better understood with reference to the following drawings. The components in the drawings are not necessarily drawn to scale, emphasis instead being placed upon clearly illustrating the principles of the present invention. Moreover, in the drawings, like reference numerals designate corresponding parts throughout the several views.

FIG. 1 is a schematic view of a light-emitting diode according to a preferred embodiment;

FIG. 2 is similar to FIG. 1, showing light paths associated with the light-emitting diode of FIG. 1; and

FIG. 3 is a schematic view of a conventional light-emitting diode.

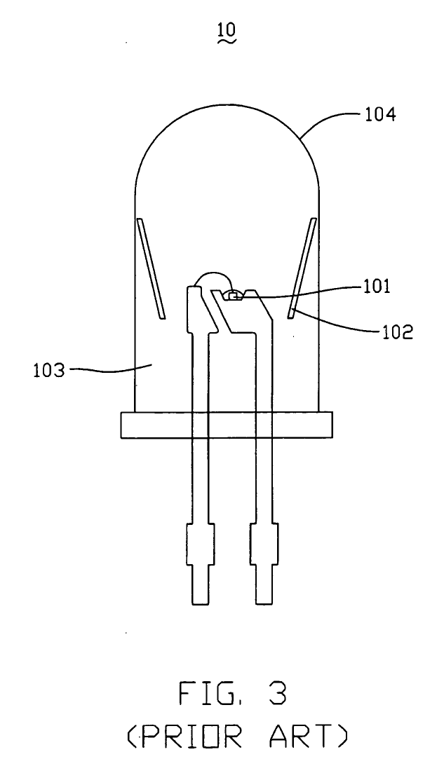

Corresponding reference characters indicate corresponding parts throughout the drawing. The exemplifications set out herein illustrate at least one preferred embodiment of the present invention, in one form, and such exemplifications are not to be construed as limiting the scope of the invention in any manner.

### DETAILED DESCRIPTION OF PREFERRED EMBODIMENTS

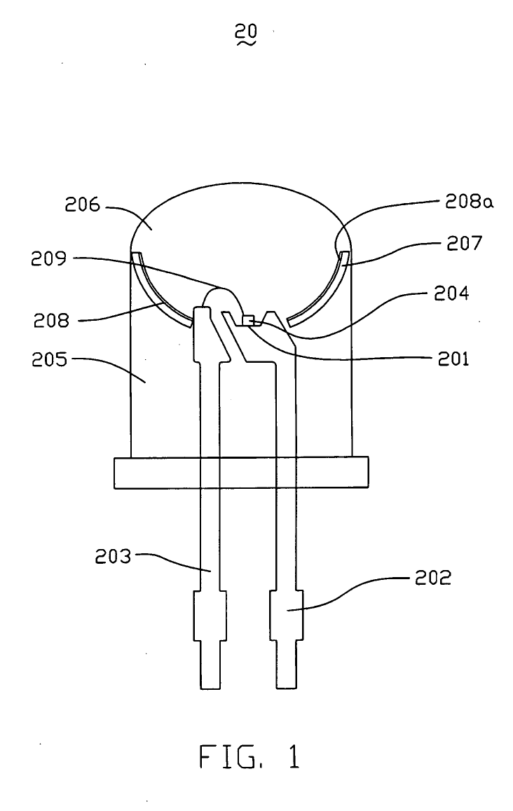

Referring to FIG. 1, a light-emitting diode 20 according to a first preferred embodiment is shown. The light-emitting diode 20 includes a first electrode 202, a second electrode 203, a light-emitting chip 204 and a cover 205.

The first electrode 203 has a supporting portion 201. The light-emitting chip 204 is disposed on the supporting portion 201 and electrically connected to the first electrode 202. The second electrode 203 is electrically connected to light-emitting chip 204 via a metal wire 209.

The light-emitting chip 204, the first electrode 202 and the second electrode 203 are enclosed in the cover 205. Terminals of the first electrode 202 and the second electrodes 203 extend outside of the cover 205.

The cover 205 has a transparent aspheric portion 206 configured for converging the light beams emitted from the light-emitting chip 204. In the first embodiment, the aspheric portion 206 is an ellipsoidal portion. However, the aspheric portion 206 could be a hyperbolic or parabolic portion.

The aspheric portion 206 can eliminate an aberration of the cover 205. It does this converging and collimating light beams emitted from the light-emitting chip 204 so that emission performance of the light-emitting diode 20 can be improved compared to that of the conventional light-emitting diode 10 with a spherical surface. In addition, emitting directivity of the light-emitting chip 204 is also improved.

The cover 205 can be made with an injection molding technique, and can be made of resin material, such as polyester, acrylic resin, fluororesin or polyvinyl chloride. The polyester includes polyethylene terephthalate (PET) and polyethylene naphthalate (PEN). The acrylic resin includes polymethyl methacrylate and modified polymethyl methacrylate. The fluororesin includes polyvinylidene fluoride (PVDF).

The light-emitting diode 20 further includes a reflection mirror 207 with a curved reflection surface 208 disposed in the cover 205. The reflection mirror 207 surrounds and faces the light-emitting chip 204. Preferably, a reflection film 208a for reflecting light beams is coated on the curved reflection surface 208 of the reflection mirror 207. The reflection film 208a is configured for increasing the reflection rate of the reflection mirror 207, and can be formed by for example an evaporating method. The reflection film 208a is preferably made of a metallic material, such as aluminum. The metallic material preferably has a good reflectivity ability and good thermal conductivity. Therefore, the metallic reflection film 208a can reflect light beams and simultaneously dissipate the heat from the light-emitting chip 204.

The curved reflection surface 208 has a surface area greater than that of a conventional horn-shaped surface 102. Accordingly, the reflection mirror 207 exhibits an increased efficiency of reflection.

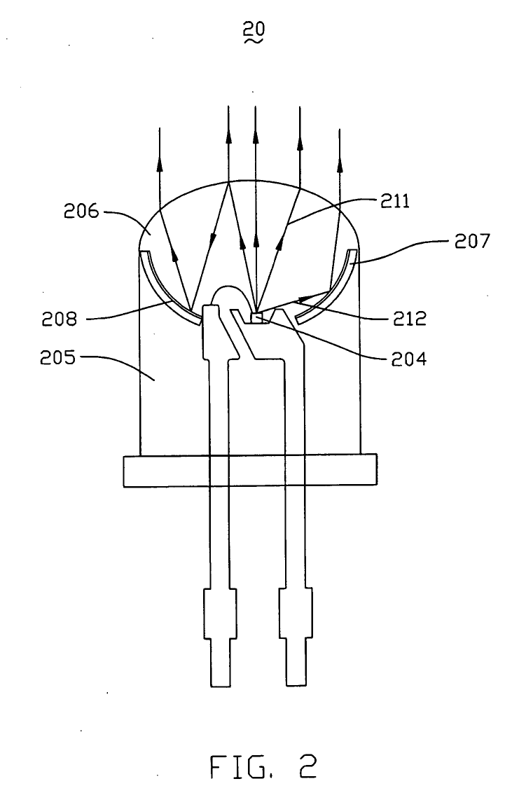

Referring to FIG. 2, this shows light paths associated with the light-emitting diode of FIG. 1. A method for improving emitting directivity of light beams emitted from a light-emitting chip according to a second preferred embodiment is provided. The method includes the steps in no particular of:

providing a cover 205 having a transparent aspheric portion 206;

providing a reflection mirror 207 having a curved reflection surface 208;

providing a light-emitting chip 204 for emitting first light beams 211 emitted toward the transparent aspheric portion 206, and second light beams 212 emitted toward the curved reflection surface 208;

arranging the reflection mirror 207 to surround the light-emitting chip 204 so as to reflect the second light beams 212 toward the transparent aspheric portion 206;

disposing the light-emitting chip 204 in the cover 205 in a manner such that the first beams 211 and the second light beams 212 exiting from the cover 205 are directed to emit toward a substantially common direction.

Therefore, light beams emitted from the light-emitting chip 204 exiting through the aspheric portion 206 can be converged and collimated so that emission performance of the light-emitting diode 20 can be improved compared to that of the conventional light-emitting diode 10 with a spherical surface. In addition, emitting directivity of the light-emitting chip 204 is also improved.

It is believed that the present embodiment and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A light-emitting diode comprising:
a first electrode having a supporting portion;
a second electrode opposite to the first electrode;
a light-emitting chip configured for emitting light beams therefrom, the light-emitting chip being disposed on the supporting portion, and electrically connected to the first electrode and the second electrode; and
a cover enclosing the light-emitting chip, and portions of the first and second electrodes therein, the cover having a transparent aspheric portion configured for converging the light beams emitted from the light-emitting chip.

2. The light-emitting diode of claim 1, wherein the aspheric portion is an ellipsoidal portion.

3. The light-emitting diode of claim 1, wherein the aspheric portion is a hyperbolic portion.

4. The light-emitting diode of claim 1, wherein the aspheric portion is a parabolic portion.

5. The light-emitting diode of claim 1, further comprising a reflection mirror with a curved reflection surface disposed in the cover, the reflection mirror surrounding and facing the light-emitting chip.

6. The light-emitting diode of claim 5, wherein the reflection mirror comprises a reflection film coated on the curved reflection surface thereof.

7. The light-emitting diode of claim 6, wherein the reflection film is comprised of a metallic material.

8. The light-emitting diode of claim 1, wherein the transparent portion of the cover is comprised of resin material.

9. The light-emitting diode of claim 8, wherein the resin material is selected from the group consisted of polyester, acrylic resin, fluororesin and polyvinylchloride.

10. A method for improving emitting directivity of light beams, emitted from a light-emitting chip, the method comprising the steps of:
providing a cover having a transparent aspheric portion;
providing a reflection mirror having a curved reflection surface;
providing a light-emitting chip for emitting first light beams emitted toward the transparent aspheric portion, and second light beams emitted toward the curved reflection surface;
arranging the reflection mirror to surround the light-emitting chip so as to reflect the second light beams toward the transparent aspheric portion;
disposing the light-emitting chip in the cover in a manner such that the first and second light beams exiting from the cover are directed to emit toward a substantially common direction.
